(19) United States
(12) Patent Application Publication
(10) Pub. No.: US 2018/0199463 A1
(43) Pub. Date: Jul. 12, 2018

(54) ELECTRONIC DEVICE

(71) Applicant: FUJITSU LIMITED, Kawasaki-shi (JP)

(72) Inventors: Jun Oota, Fukuoka (JP); Hiroyuki Shouyama, Fukuoka (JP); Kazuhiro Watanabe, Fukuoka (JP); DAIYU IRIE, Fukuoka (JP)

(73) Assignee: FUJITSU LIMITED, Kawasaki-shi (JP)

(21) Appl. No.: 15/860,243

(22) Filed: Jan. 2, 2018

(30) Foreign Application Priority Data
Jan. 12, 2017 (JP) 2017-003296

(51) Int. Cl. H05K 7/20

(52) U.S. Cl. CPC H05K 7/20145

(57) ABSTRACT

An electronic device includes an electronic component; a conductive housing that has electric conductivity and a vent port and houses the electronic component; a fan that is housed within the conductive housing; a conductive duct that has electric conductivity and couples the vent port and the fan; and a conductive partition member that has electric conductivity, is provided in an air passage of the conductive duct, and partitions the air passage along a passing direction of wind.

### CROSS-REFERENCE TO RELATED APPLICATION

This application is based upon and claims the benefit of priority of the prior Japanese Patent Application No. 2017-003296, filed on Jan. 12, 2017, the entire contents of which are incorporated herein by reference.

### FIELD

The technology disclosed herein is related to an electronic device.

### BACKGROUND

There is an electronic device including: a conductive housing that houses an electronic component and that blocks electromagnetic waves; and a fan that is provided to the conductive housing and that cools the interior of the conductive housing (see, for example, Japanese Laid-open Patent Publication No. 2010-103581 and Japanese Laid-open Patent Publication No. 11-186767).

In such an electronic device, a vent port is formed in the conductive housing. When the fan is operated, air is supplied through the vent port to the interior of the conductive housing, or air within the conductive housing is discharged through the vent port.

Meanwhile, the efficiency of cooling the interior of the conductive housing is considered to be enhanced by increasing the size of the vent port of the conductive housing.

However, when the size of the vent port of the conductive housing is increased, an electromagnetic wave easily passes through the vent port, so that there is a possibility that blocking performance for electromagnetic waves decreases. Even when the size of the vent port of the conductive housing is increased, it is desirable to be able to inhibit a decrease in the blocking performance for electromagnetic waves.

### SUMMARY

According to an aspect of the invention, an electronic device includes an electronic component; a conductive housing that has electric conductivity and a vent port and houses the electronic component; a fan that is housed within the conductive housing; a conductive duct that has electric conductivity and couples the vent port and the fan; and a conductive partition member that has electric conductivity, is provided in an air passage of the conductive duct, and partitions the air passage along a passing direction of wind.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded perspective view illustrating an electronic device according to an embodiment;

FIG. 2 is an exploded perspective view illustrating a fan unit illustrated in FIG. 1;

FIG. 3 is a cross-sectional view of the fan unit illustrated in FIG. 1, taken along a passing direction of wind;

FIG. 4 is a front view of a duct module illustrated in FIG. 2, as seen from the vent port side of a conductive housing;

FIG. 5 is a graph illustrating a speed distribution of wind sent out from a fan module;

FIG. 6 is a partially enlarged view of FIG. 3 illustrating tapered portions of tubular portions;

FIG. 7 is a partially enlarged view of FIG. 3 illustrating chamfered portions of the tubular portions;

FIG. 8 is a cross-sectional view illustrating an example of a test finger;

FIG. 9 depicts graphs each representing the relationship between the distance from the fan module to a perforated metal, a louver, or a slit and the wind volume of wind passing through the perforated metal, the louver, or the slit;

FIG. 10 is a front view illustrating an example of the perforated metal;

FIG. 11 depicts graphs each representing the relationship between the wind volume and the static pressure of wind passing through the perforated metal;

FIG. 12 is a front view of the duct module for calculating an opening ratio as seen from the vent port side of the conductive housing;

FIG. 13 depicts graphs each representing the relationship between the distance from the fan module to the perforated metal, the louver, or the slit and a noise level;

FIG. 14 is a cross-sectional view, corresponding to FIG. 3, illustrating a modification of the duct module; and

FIG. 15 is an enlarged cross-sectional view, corresponding to FIG. 6, illustrating a modification of the tubular portions.

### DESCRIPTION OF EMBODIMENT

Hereinafter, an embodiment of the technology disclosed herein will be described.

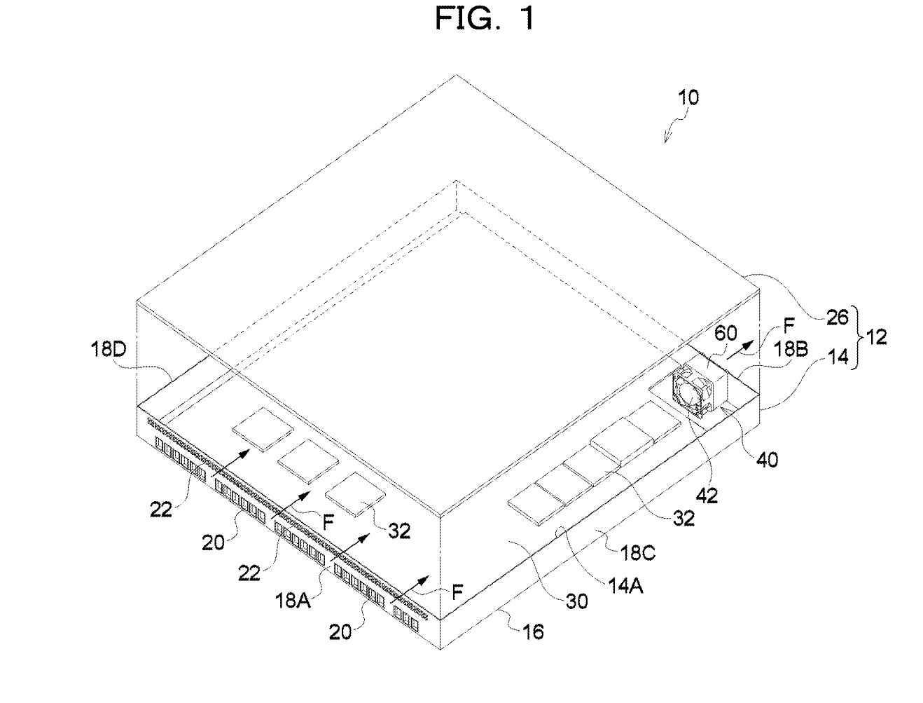

As illustrated in FIG. 1, an electronic device 10 according to the present embodiment is, for example, a rack-mount type server or the like housed in a rack that is not illustrated. The electronic device 10 includes a conductive housing 12, a printed board 30, and a fan unit 40.

The conductive housing 12 includes a housing body 14 and a lid body 26. The housing body 14 is formed in a thin box shape that is open at the upper side thereof. The housing body 14 has a housing opening 14A through which the printed board 30 or the like is housed. The housing opening 14A is opened or closed by the lid body 26.

The lid body 26 is detachably mounted on the housing body 14. The lid body 26 and the housing body 14 are formed from a metallic material having electric conductivity. Accordingly, the conductive housing 12 serves as an electromagnetic wave shield that block electromagnetic waves.

The housing body 14 includes a bottom wall portion 16 and a plurality of side wall portions 18A, 18B, 18C, and 18D. The plurality of side wall portions 18A, 18B, 18C, and 18D are erected from an outer peripheral portion of the bottom wall portion 16. A plurality of coupling ports 20 through which cables that are not illustrated are coupled are formed in the side wall portion 18A at one side.

A plurality of air holes 22 are formed in the side wall portion 18A at the one side. Each air hole 22 is a through hole that has a small diameter and that is able to limit passing of electromagnetic waves. These air holes 22 serve as suction holes through which outside air is taken into the conductive housing 12 as indicated by arrows F when the later-described fan unit 40 operates. The arrows F illustrated in the respective drawings indicate flow of wind.

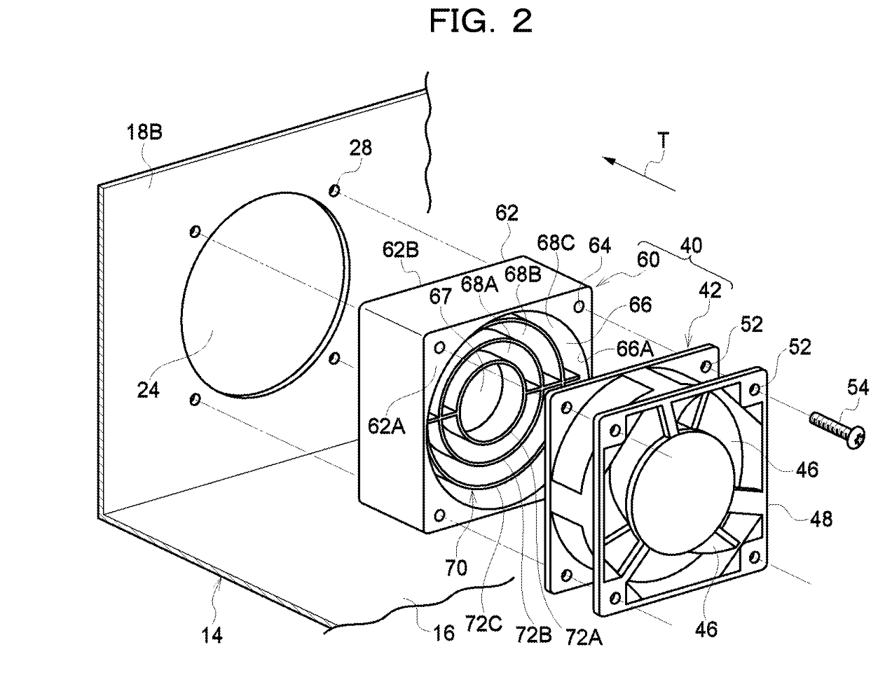

A vent port 24 is formed in the side wall portion 18B at another side opposing the side wall portion 18A at the one side as illustrated in FIG. 2. The vent port 24 is a circular through hole. The later-described fan unit 40 is coupled to the vent port 24.

As illustrated in FIG. 1, the printed board 30 is housed in the conductive housing 12. A plurality of electronic components 32 such as a central processing unit (CPU) or a memory are mounted on the printed board 30. These electronic components 32 generate heat by consuming power. The electronic components 32 emit electromagnetic waves.

The fan unit 40 is housed in the conductive housing 12. The fan unit 40 is an air-cooling type cooling device that generates wind (cooling wind) for cooling the interior of the conductive housing 12. The fan unit 40 includes a fan module 42 and a duct module 60.

As illustrated in FIG. 2, the fan module 42 is disposed opposite to the vent port 24 of the conductive housing 12. The fan module 42 is an axial-flow fan that discharges air within the conductive housing 12 through the vent port 24 to the outside of the conductive housing 12. The fan module 42 and the vent port 24 are coupled to each other via the later-described duct module 60.

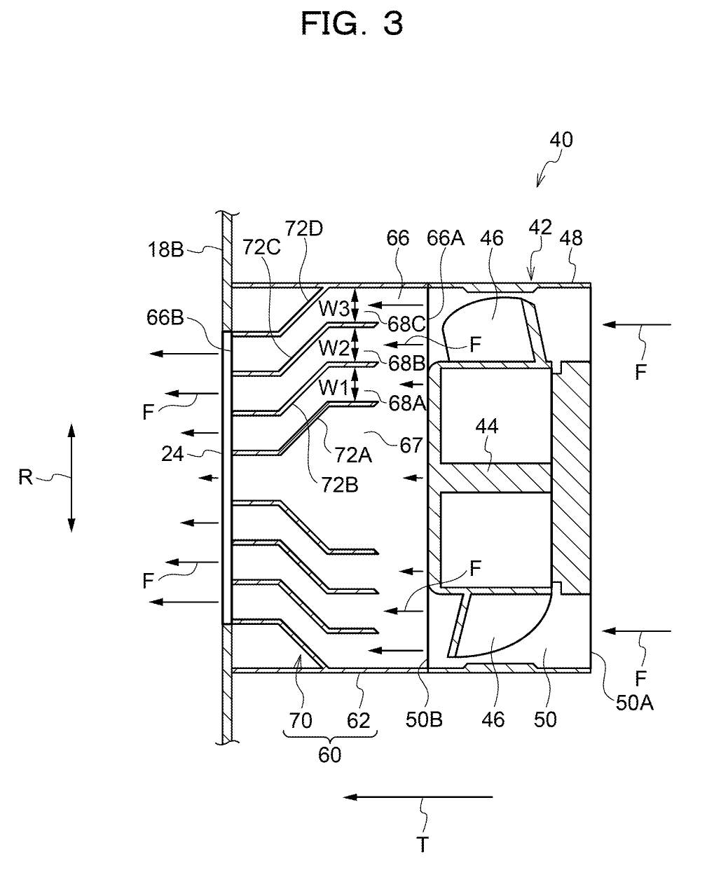

As illustrated in FIG. 3, the fan module 42 includes a hub 44, a plurality of blades (propellers) 46, and a fan casing 48. The hub 44 is formed in a columnar shape. The hub 44 is provided on an output shaft of an electric motor that is not illustrated. The plurality of blades 46 are provided on the outer peripheral surface of the hub 44.

The plurality of blades 46 radially extend from the outer peripheral surface of the hub 44 with the hub 44 as a center. These blades 46 and the hub 44 are rotatably housed in the fan casing 48.

The fan casing 48 is formed in a rectangular parallelepiped shape. The fan casing 48 has a housing chamber 50 that houses the hub 44 and the plurality of blades 46. The housing chamber 50 has an air intake port 50A and an air sending port 50B. The air intake port 50A is located at one side in the axial direction of the hub 44. Meanwhile, the air sending port 50B is located at the other side in the axial direction of the hub 44. The fan casing 48 is disposed in a state where the air sending port 50B faces the vent port 24.

Here, when the electric motor is operated, the hub 44 and the plurality of blades 46 rotate (turn) in a predetermined direction. Accordingly, air is sucked through the air intake port 50A into the housing chamber 50 as illustrated by the arrows F. The air sucked into the housing chamber 50 flows along the axial direction of the hub 44 and is sent out through the air sending port 50B as illustrated by the arrows F. Accordingly, wind is generated.

The duct module 60 is disposed between the air sending port 50B of the fan module 42 and the vent port 24 of the conductive housing 12. The duct module 60 serves as a pipe (air guiding pipe) that guides the wind generated by the fan module 42, to the vent port 24 as illustrated by an arrow T.

The duct module 60 includes a conductive duct 62 and a conductive partition member 70. The conductive duct 62 and the conductive partition member 70 are formed from a metallic material having electric conductivity. Accordingly, the conductive duct 62 and the conductive partition member 70 also serve as electromagnetic wave shields that block electromagnetic waves passing through the vent port 24.

As illustrated in FIG. 2, similarly to the fan casing 48, the conductive duct 62 is formed in a rectangular parallelepiped shape. The conductive duct 62 has a first mounting surface 62A and a second mounting surface 62B. The first mounting surface 62A is formed at one side of the conductive duct 62 (at the fan module 42 side). The fan casing 48 is mounted on the first mounting surface 62A.

The second mounting surface 62B is formed at the other side of the conductive duct 62 (at the vent port 24 side). That is, the second mounting surface 62B is formed at the side of the conductive duct 62 opposite to the first mounting surface 62A. The side wall portion 18B of the conductive housing 12 is mounted on the second mounting surface 62B.

Specifically, a mounting hole 52 is formed in each corner portion of the fan casing 48. Similarly to this, a mounting hole 64 is formed in each corner portion of the first mounting surface 62A and the second mounting surface 62B of the conductive duct 62. Furthermore, a plurality of mounting holes 28 are formed in the side wall portion 18B of the conductive housing 12 and at the outer peripheral portion of the vent port 24.

For example, screws 54 are inserted into the mounting holes 28, 52, and 64. The fan casing 48 is fixed to the first mounting surface 62A of the conductive duct 62, and the second mounting surface 62B of the conductive duct 62 is also fixed to the side wall portion 18B of the conductive housing 12, by the screws 54.

A structure for mounting the fan casing 48, the conductive duct 62, and the conductive housing 12 is changeable as appropriate.

An air passage 66 is formed in a center portion of the first mounting surface 62A of the conductive duct 62. The air passage 66 is a circular through hole that penetrates the conductive duct 62 and that reaches the first mounting surface 62A and the second mounting surface 62B. As illustrated in FIG. 3, the air passage 66 has an air passage inlet 66A and an air passage outlet 66B. The air passage inlet 66A is formed in the first mounting surface 62A. The air passage inlet 66A is coupled to the air sending port 50B of the fan casing 48.

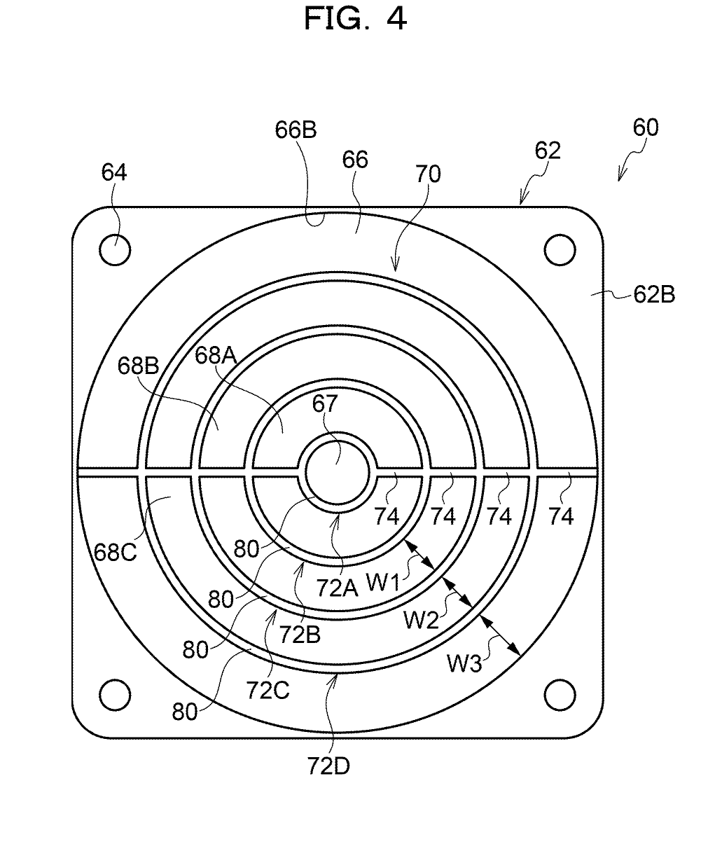

Meanwhile, the air passage outlet 66B is formed in the second mounting surface 62B (see FIG. 4). The air passage outlet 66B is coupled to the vent port 24 of the conductive housing 12. Accordingly, the air sending port 50B of the fan casing 48 and the vent port 24 of the conductive housing 12 are coupled to each other via the air passage 66 of the conductive duct 62. The size of the air passage outlet 66B and the size of the vent port 24 are equal to or nearly equal to each other.

Here, as illustrated by the arrows F, the wind generated by the fan module 42 flows through the air passage inlet 66A of the conductive duct 62 into the air passage 66. As illustrated by the arrows F, the wind passes through the air passage 66 and is sent through the air passage outlet 66B and the vent port 24 of the conductive housing 12 to the outside of the conductive housing 12.

An arrow T indicates the passing direction of the wind passing through the air passage 66. The passing direction of the wind coincides with the axial direction of the air passage 66.

The conductive partition member 70 is provided in the air passage 66 of the conductive duct 62. The conductive partition member 70 partitions the air passage 66 along the passing direction of the wind passing through the air passage 66 (the arrow T direction). Accordingly, a circular air passage 67 and a plurality of annular air passages 68A, 68B, and 68C are formed in the air passage 66 so as to extend in the passing direction of the wind.

Specifically, the conductive partition member 70 has a plurality of tubular portions 72. The plurality of tubular portions 72 are formed in tubular shapes having different diameters. The tubular portions 72 are disposed such that the axial direction thereof coincides with the passing direction of the wind flowing through the air passage 66 (the arrow T direction).

The plurality of tubular portions 72 are disposed so as to be coaxial with each other. The plurality of tubular portions 72 are disposed so as to be coaxial with the circular air passage 66. Furthermore, as illustrated in FIG. 4, the adjacent tubular portions 72 are coupled to each other via a rib-like coupling portion 74 extending in the radial direction of the air passage 66 (an arrow R direction).

The conductive partition member 70 of the present embodiment has four tubular portions 72 having different diameters. Thus, hereinafter, for convenience of explanation, the four tubular portions 72 are referred to as a first tubular portion 72A, a second tubular portion 72B, a third tubular portion 72C, and a fourth tubular portion 72D in order from one having a smaller diameter. The first tubular portion 72A, the second tubular portion 72B, the third tubular portion 72C, and the fourth tubular portion 72D are collectively referred to as tubular portions 72.

As illustrated in FIG. 3, the plurality of tubular portions 72 partition the air passage 66 into the circular air passage 67 and the plurality of annular air passages 68A, 68B, and 68C in the radial direction (the arrow R direction). The circular air passage 67 is formed inside the first tubular portion 72A. Meanwhile, each of the annular air passages 68A, 68B, and 68C is formed between the adjacent tubular portions 72.

Specifically, the annular air passage 68A is formed between the outer peripheral surface of the first tubular portion 72A and the inner peripheral surface of the second tubular portion 72B. The annular air passage 68B is formed between the outer peripheral surface of the second tubular portion 72B and the inner peripheral surface of the third tubular portion 72C. Furthermore, the annular air passage 68C is formed between the outer peripheral surface of the third tubular portion 72C and the inner peripheral surface of the fourth tubular portion 72D. The wind generated by the fan module 42 flows through the circular air passage 67 and the plurality of annular air passages 68A, 68B, and 68C. The circular air passage 67 and the plurality of annular air passages 68A, 68B, and 68C are an example of a plurality of small air passages.

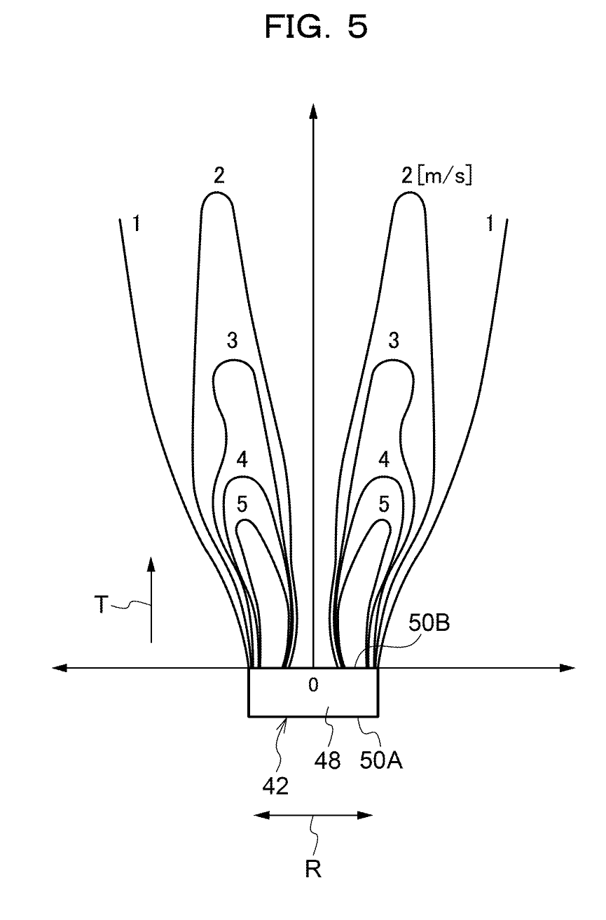

Here, FIG. 5 illustrates a wind speed distribution of the wind generated by the fan module 42. As illustrated in FIG. 5, the wind speed of the wind increases from the center of the fan module 42 toward the outer periphery thereof. Therefore, the wind volume of the wind increases from the center of the fan module 42 toward the outer periphery thereof.

Accordingly, in the present embodiment, as illustrated in FIG. 3, air passage widths W1, W2, and W3 of the plurality of annular air passages 68A, 68B, and 68C are set in accordance with the wind speed and the wind volume of the wind generated by the fan module 42. Specifically, the air passage widths W1, W2, and W3 of the plurality of annular air passages 68A, 68B, and 68C are increased from the center side of the fan module 42 toward the outer peripheral side thereof (W1 <W2 <W3). That is, the air passage width W3 of the annular air passage 68C at the outer peripheral side of the fan module 42 is made larger than the air passage width W1 of the annular air passage 68A at the center side of the air passage 66.

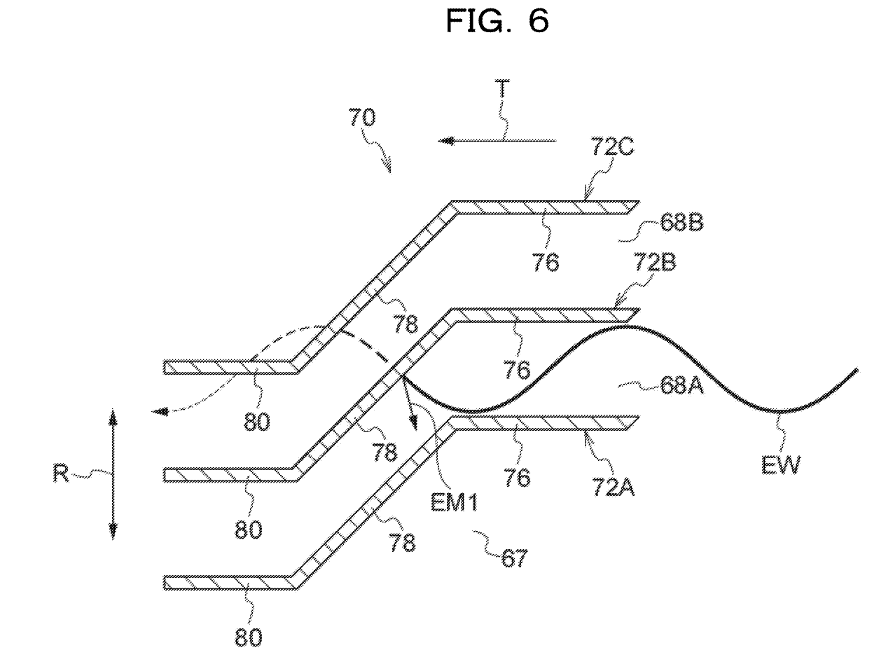

As illustrated in FIG. 6, each tubular portion 72 has a first straight portion 76, a tapered portion 78, and a second straight portion 80. The first straight portion 76 and the second straight portion 80 are formed in a cylindrical shape extending in the passing direction of the wind (in the arrow T direction). In FIG. 6, the fourth tubular portion 72D is not illustrated.

The first straight portion 76 is disposed at the fan module 42 side. Meanwhile, the second straight portion 80 is disposed at the vent port 24 side (the arrow T direction side) with respect to the first straight portion 76. The second straight portion 80 has a smaller diameter than the first straight portion 76. The second straight portion 80 is disposed so as to be coaxial with the first straight portion 76. The second straight portion 80 and the first straight portion 76 are coupled to each other via the tapered portion 78. The first straight portion 76 and the second straight portion 80 are an example of a straight portion.

The tapered portion 78 is formed in a truncated cone shape having a diameter that decreases from the first straight portion 76 toward the second straight portion 80. The tapered portion 78 is inclined relative to the passing direction of the wind. The tapered portion 78 is an example of an inclined portion.

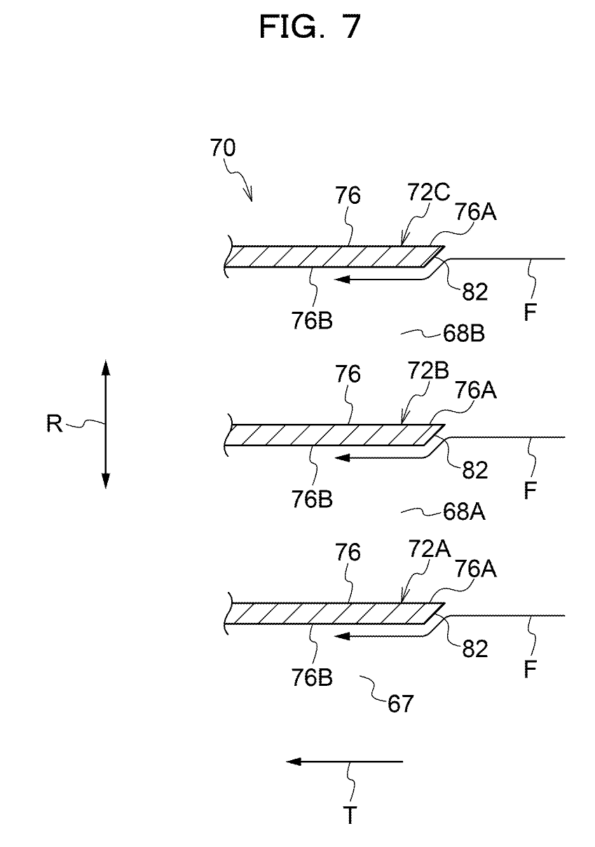

As illustrated in FIG. 7, a chamfered portion 82 is provided at an inner peripheral surface 76B side of an end portion 76A of each first straight portion 76. The chamfered portion 82 is an inclined surface that is inclined relative to the passing direction of the wind (the arrow T direction). Accordingly, as illustrated by the arrows F, the wind generated by the fan module 42 easily flows along the chamfered portion 82 into the circular air passage 67 or the annular air passage 68A or 68B.

As illustrated in FIG. 4, the second straight portion 80 serves as a finger guard. Specifically, the air passage widths W1, W2, and W3 of the annular air passages 68A, 68B, and 68C, each of which is formed between the adjacent second straight portions 80, are set such that a finger of a person or the like does no come into contact with the blades 46 of the fan module 42. For example, a test finger is used for setting these air passage widths W1, W2, and W3

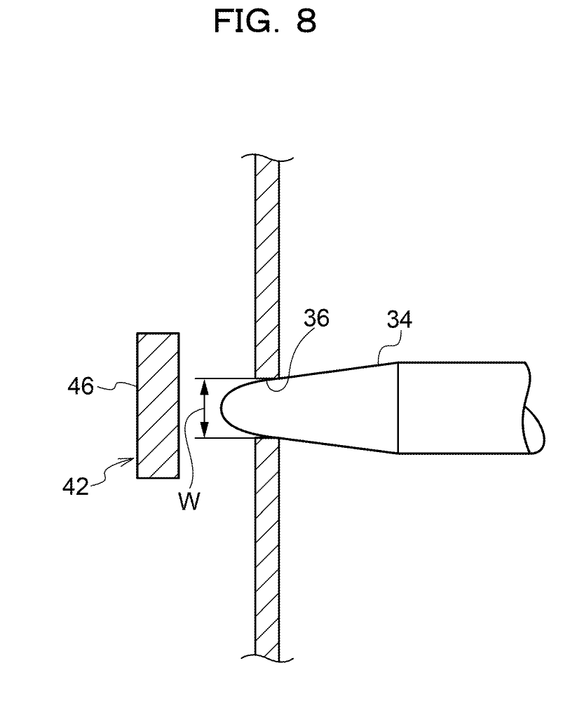

Specifically, FIG. 8 illustrates a setting example of the width W of the air passage 36. The width W of the air passage 36 is set such that a test finger 34 is not in contact with the blades 46 of the fan module 42 when the test finger 34 is inserted into the air passage 36. By the same method, the air passage widths W1, W2, and W3 of the annular air passages 68A, 68B, and 68C of the present embodiment are also set as appropriate by using the test finger.

The test finger is specified in IEC60950-1, which is an IEC (International Electronical Commission) standard.

Next, advantageous effects of the present embodiment will be described.

First, the efficiency of cooling the interior of the conductive housing 12 will be described.

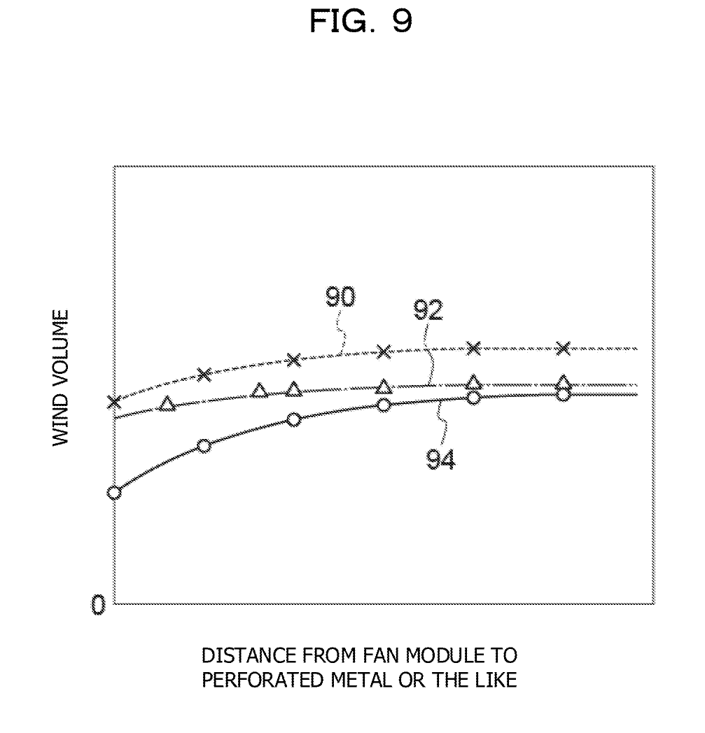

FIG. 9 depicts graphs 90, 92, and 94 each representing the wind volume of wind passing through a perforated metal, a louver, or a slit that is provided before the air sending port of the fan module as a comparative example.

The horizontal axis in FIG. 9 indicates the distance from the air sending port of the fan module to the perforated metal, the louver, or the slit. The vertical axis in FIG. 9 indicates the wind volume of the wind passing through the perforated metal, the louver, or the slit.

The graph 90 represents the wind volume of the wind passing through the perforated metal. The graph 92 represents the wind volume of the wind passing through the louver. Furthermore, the graph 92 represents the wind volume of the wind passing through the slit. The opening ratios of the perforated metal, the louver, and the slit are 37%, 27%, and 23%, respectively.

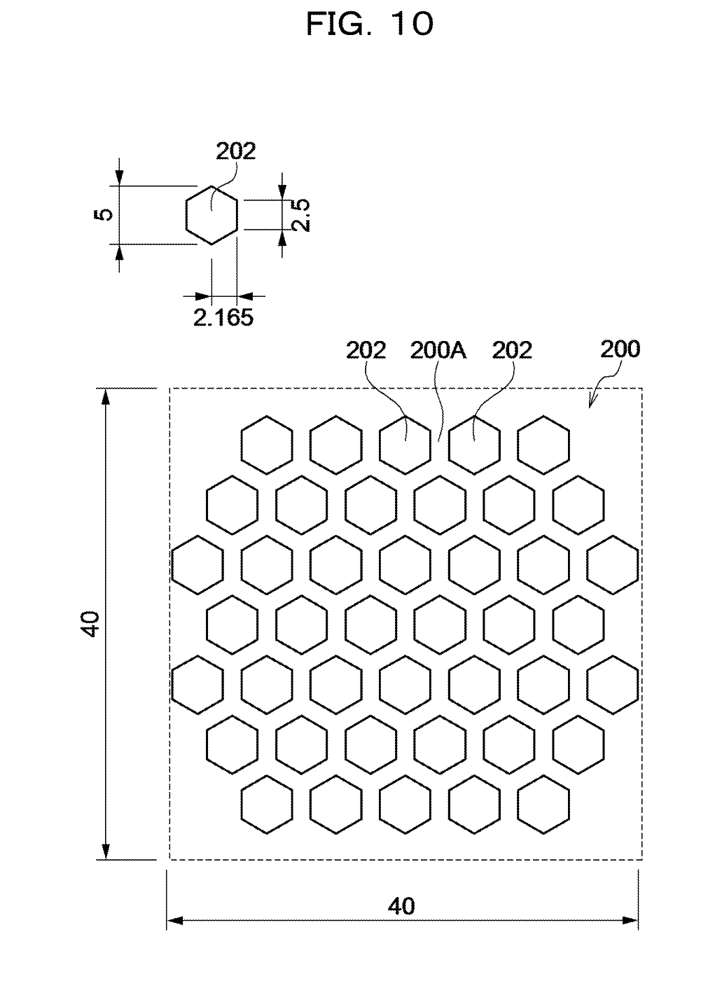

For giving a supplemental description for the perforated metal, FIG. 10 illustrates an example of a perforated metal 200. The perforated metal 200 has a plurality of air holes 202 arranged in a staggered manner. Each air hole 202 is a through hole that has a small diameter and that is able to block electromagnetic waves. Each air hole 202 has a hexagonal shape.

As illustrated by the graphs 90, 92, and 94 in FIG. 9, the wind volume is the largest in the case of the perforated metal having the highest opening ratio, among the perforated metal, the louver, and the slit. Therefore, in the case of the perforated metal among the perforated metal, the louver, and the slit, the efficiency of cooling the interior of the conductive housing becomes highest. As described above, the perforated metal has a plurality of air holes that have a small diameter and through which electromagnetic waves are difficult to pass. Thus, with the perforated metal, it is possible to ensure blocking performance for electromagnetic waves.

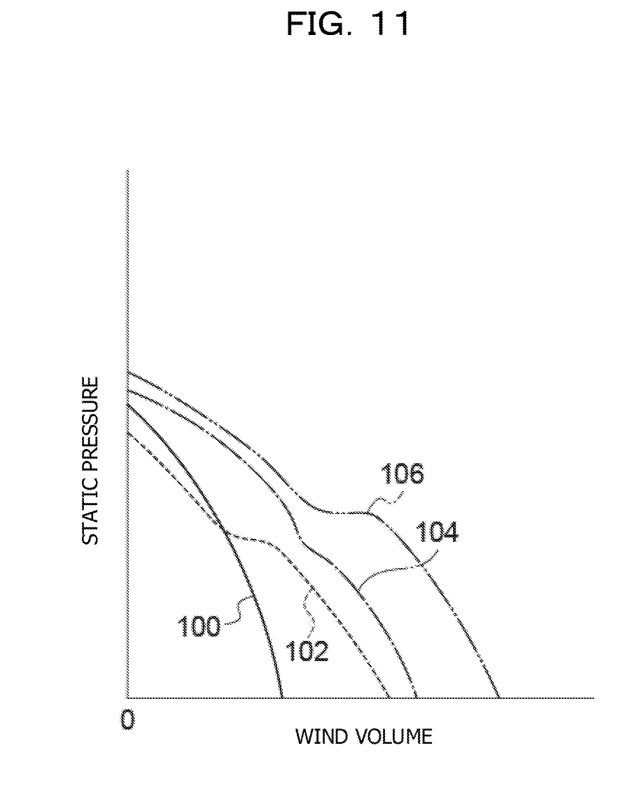

Meanwhile, FIG. 11 depicts graphs 100, 102, 104, and 106 each representing the relationship between the wind volume and the static pressure of wind passing through the perforated metal. The graph 100 represents the wind volume of the wind passing through the perforated metal provided at the air sending port of the fan module. The graph 102 represents the wind volume of the wind passing through the perforated metal provided at the air intake port of the fan module. Furthermore, the graph 104 represents the wind volume of the wind passing through the perforated metal provided at a position away from the air intake port of the fan module by 10 cm. Meanwhile, the graph 106 represents the wind volume of the wind in the case where the perforated metal is not provided.

As represented by the graphs 100, 102, 104, and 106 in FIG. 11, when the perforated metal is provided, the wind volume decreases as compared to the case where the perforated metal is not provided. Therefore, when the perforated metal is provided, the efficiency of cooling the interior of the conductive housing 12 decreases as compared to the case where the perforated metal is not provided.

The cause for this is thought to be that when a description is given with the perforated metal 200 illustrated in FIG. 10 as an example, the wind is blocked by a part 200A between the adjacent air holes 202 in the perforated metal 200, so that the wind volume of the wind passing through the perforated metal 200 decreases.

As described above, the perforated metal has room for improvement in terms of decrease in the efficiency of cooling the interior of the conductive housing 12.

On the other hand, in the present embodiment, as illustrated in FIG. 3, the air passage 66 of the conductive duct 62 is partitioned into the circular air passage 67 and the plurality of annular air passages 68A, 68B, and 68C by the plurality of tubular portions 72 of the conductive partition member 70. As illustrated in FIG. 4, wide openings along the circumferential direction of the air passage 66 are ensured at the annular air passages 68A, 68B, and 68C. Therefore, in the present embodiment, it is possible to increase the wind volume of the wind passing through the air passage 66 of the conductive duct 62, as compared to the case with the perforated metal.

Here, examples of calculation of the opening ratio of the air passage 66 of the conductive duct 62 according to the present embodiment and the opening ratio of the perforated metal 200 (see FIG. 10) are respectively indicated in tables below. From Tables 2 and 3, it is found that the opening ratio of the air passage 66 of the conductive duct 62 according to the present embodiment is higher than the opening ratio of the perforated metal 200. Therefore, in the present embodiment, it is possible to make the efficiency of cooling the interior of the conductive housing 12 higher than that with the perforated metal 200.

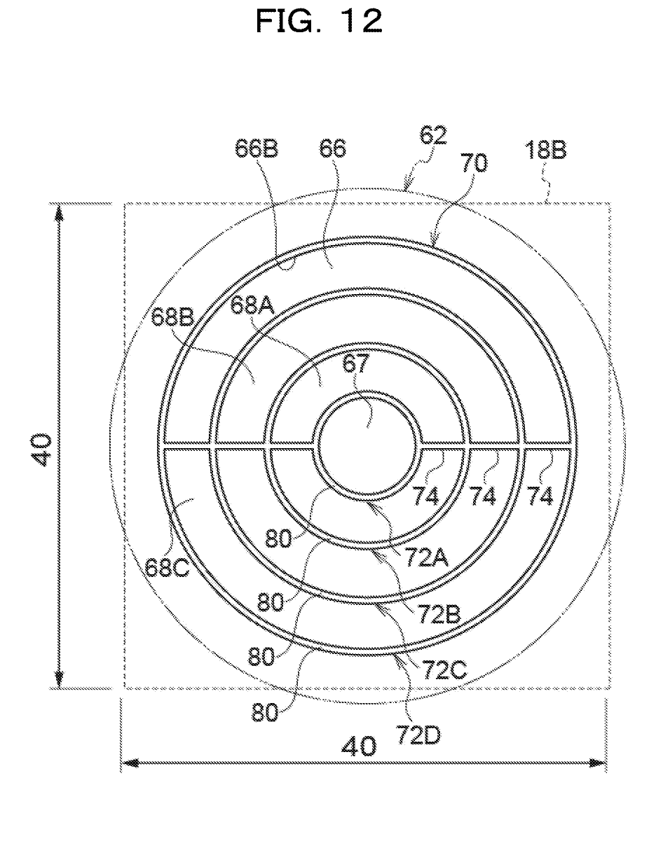

The opening ratio is, for example, the ratio of the opening areas of the circular air passage 67 and the plurality of annular air passages 68A, 68B, and 68C relative to a reference area (40 mm×40 mm) as illustrated in FIG. 12 in the case of the conductive duct 62 according to the present embodiment.

[Table 1]

Opening ratio of air passages of conductive duct according to present embodiment

TABLE 1
Opening ratio of air passages of conductive duct according to
present embodiment

| | Circular | Annular | Annular | Annular | | |
|---|---|---|---|---|---|---|
| | air | air | air | air | | |
| | passage | passage | passage | passage | | Opening |
| | 67 | 68A | 68B | 68C | Total | ratio |
| Opening | 38.485 | 146.796 | 259.894 | 372.991 | 818.166 | 51.1% |
| area | | | | | | |
| (mm²) | | | | | | |

[Table 2]

Opening ratio of perforated metal according to comparative embodiment

TABLE 2
Opening ratio of perforated metal
according to comparative embodiment

| Opening area | | | |
|---|---|---|---|
| of air holes | Number of | | Opening |
| (mm²) | air holes | Total | ratio |
| 16.238 | 42 | 681.996 | 42.6% |

In the present embodiment, as illustrated in FIG. 3, the air passage widths W1, W2, and W3 of the plurality of annular air passages 68A, 68B, and 68C are set in accordance with the wind speed and the wind volume of the wind generated by the fan module 42. Specifically, the air passage widths W1, W2, and W3 of the plurality of annular air passages 68A, 68B, and 68C are increased from the center side of the fan module 42 toward the outer peripheral side thereof (W1 <W2 <W3). Accordingly, the wind formed by the fan module 42 easily flows through the plurality of annular air passages 68A, 68B, and 68C. Therefore, cooling performance for the conductive housing 12 further improves.

Furthermore, the plurality of tubular portions 72 of the conductive partition member 70 are disposed so as to be coaxial with the circular air passage 66. Accordingly, for example, the air passage width W1 of the annular air passage 68A becomes equal or nearly equal at both sides in the radial direction of the air passage 66. Similarly to this, for example, the air passage width W2 of the annular air passage 68B becomes equal or nearly equal at both sides in the radial direction of the air passage 66. Moreover, for example, the air passage width W3 of the annular air passage 68C becomes equal or nearly equal at both sides in the radial direction of the air passage 66. Therefore, unevenness of the wind volume of the wind passing through the air passage 66 is inhibited.

Furthermore, in the present embodiment, as illustrated in FIG. 4, the plurality of tubular portions 72, which partition the air passage 66 of the conductive duct 62, serve as a finger guard. Therefore, in the present embodiment, it is possible to increase the opening ratio of the air passage 66 while entry of a finger or the like into the air passage 66 of the conductive duct 62 is inhibited.

Next, blocking performance for electromagnetic waves will be described.

As illustrated in FIG. 6, each tubular portion 72 of the conductive partition member 70 has the tapered portion 78. The tapered portion 78 is inclined relative to the passing direction of the wind (the arrow T direction).

Accordingly, for example, an electromagnetic wave EW that enters the annular air passage 68A of the conductive duct 62 easily passes through the tapered portion 78 of the second tubular portion 72B. Then, when the electromagnetic wave EW passes through the tapered portion 78 of the second tubular portion 72B, an induced current flows through the tapered portion 78, so that the temperature of the tapered portion 78 increases. At this time, the energy of the electromagnetic wave EW is converted to heat in the tapered portion 78, and thus the electromagnetic wave EW is attenuated.

Next, when the electromagnetic wave EW further passes through the second straight portion 80 of the tubular portion 72 of the third tubular portion 72C, the energy of the electromagnetic wave EW is further attenuated. Therefore, in the present embodiment, it is possible to attenuate the electromagnetic wave EW emitted from the interior of the conductive housing 12 to the outside of the conductive housing 12. That is, in the present embodiment, it is possible to block the electromagnetic wave EW emitted from the interior of the conductive housing 12 to the outside of the conductive housing 12. Similarly to this, in the present embodiment, it is also possible to block the electromagnetic wave EW that enters the conductive housing 12 from the outside of the conductive housing 12.

As described above, in the present embodiment, it is possible to increase the opening ratio of the air passage 66 of the conductive duct 62 while blocking performance for electromagnetic waves is ensured.

The energy amount of the electromagnetic wave EW attenuated when the electromagnetic wave EW passes through the tubular portion 72 is referred to as absorption loss A and obtained by the following equation.

A=15.4×t \sqrt{ƒ×σ×μ}

wherein f: the frequency (Hz) of the electromagnetic wave, t: the wall thickness (m) of the tubular portion (tapered portion), σ: the electric conductivity (S/m, S: siemens) of the tubular portion (tapered portion), and μ: the magnetic permeability (H/m, H: henry) of the tubular portion (tapered portion).

Here, an example of calculation of absorption loss A for two electromagnetic waves having different frequencies is indicated in a table below. The frequencies of the electromagnetic waves are 30 MHz and 1 GHz (10000 MHz). The wall thickness t of the tubular portion 72 is 0.0005 m. Furthermore, the tubular portion 72 is formed from aluminum.

TABLE 3
Absorption loss of electromagnetic waves

| Frequencies | Tubular portion (tapered portion) | | | |
|---|---|---|---|---|
| f of electro- | Wall | Electric | Magnetic | |
| magnetic | thickness | conductivity | permeability | Absorption |
| waves (Hz) | t (m) | σ (S/m) | μ (H/m) | loss A |
| 30M | 0.0005 | 37.4 × 10⁶ | 1.256665 × 10⁻⁶ | 289 |
| 1 G | | | | 1669 |

From the above table, it is found that among the two electromagnetic waves having different frequencies f, the absorption loss A for the electromagnetic wave having a higher frequency (1 GHz) is higher.

The electromagnetic wave is attenuated due to not only the above-described absorption loss A but also due to reflection loss. That is, as illustrated in FIG. 6, for example, when a part WE1 of the electromagnetic wave EW is reflected by the tapered portion 78, the electromagnetic wave EW is attenuated.

Next, the low-noise performance of the duct module will be described.

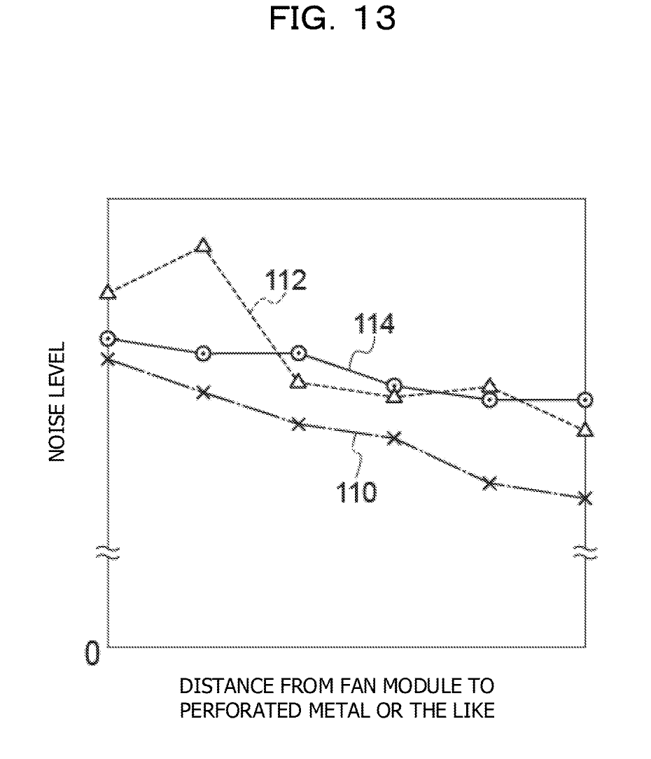

FIG. 13 depicts graphs 110, 112, and 114 each representing noise (wind noise) occurring when the wind generated by the fan module collides against the perforated metal, the louver, or the slit. As seen from the graphs 110, 112, and 114, the noise increases as the distance from the fan module 42 to the perforated metal, the louver, or the slit decreases.

On the other hand, in the present embodiment, for example, a part 200A as in the perforated metal 200 illustrated in FIG. 10 is small, and the chamfered portion 82 is provided at the end portion 76A of the first straight portion 76 of each tubular portion 72 as illustrated in FIG. 7. Accordingly, the wind generated by the fan module 42 easily flows along the chamfered portion 82. As a result, the wind noise occurring when the wind collides against the end portion 76A of the first straight portion 76 is reduced. Therefore, in the present embodiment, the low-noise performance of the duct module 60 improves.

Furthermore, the wind generated by the fan module 42 easily flows along the chamfered portions 82 into the circular air passage 67 and a plurality of the annular air passages 68A and 68B. Accordingly, the wind volume of the wind flowing through the circular air passage 67 and the plurality of the annular air passages 68A and 68B increases. Therefore, it is possible to enhance the efficiency of cooling the interior of the conductive housing 12.

Next, modifications of the above embodiment will be described.

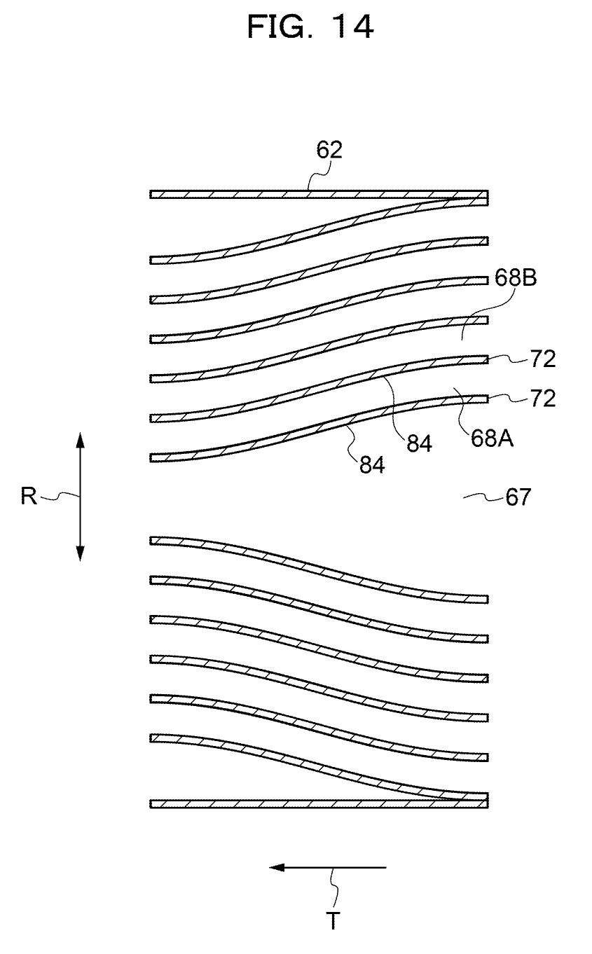

In the above embodiment, the tapered portion 78 of each tubular portion 72 is inclined relative to the first straight portion 76 and the second straight portion 80. However, as in a modification illustrated in FIG. 14, each tapered portion 84 may have a smooth curved shape (for example, a streamline shape). In this case, loss caused when the wind passes through the tapered portions 84 is reduced.

The diameter of the tapered portion 78 of the above embodiment is decreased from the fan module 42 side toward the vent port 24 side of the conductive housing 12. However, an inclined portion having a diameter that increases from the fan module 42 side toward the vent port 24 side of the conductive housing 12 may be provided in the tubular portion.

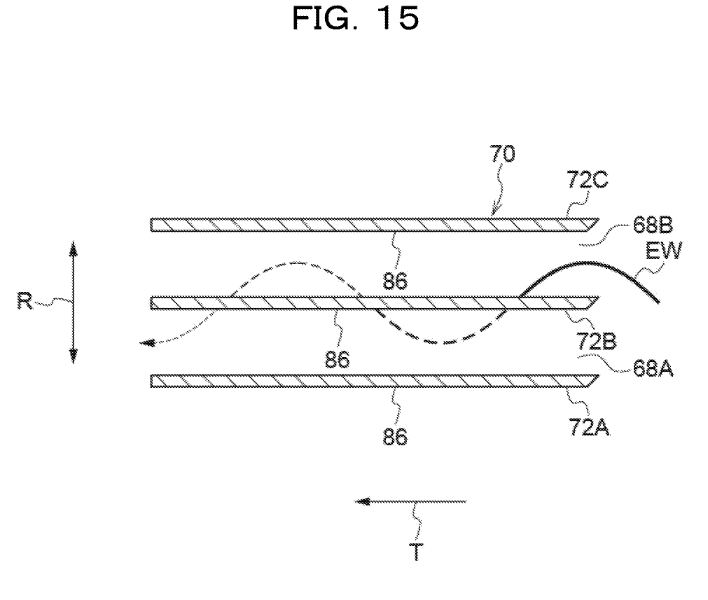

For example, as in a modification illustrated in FIG. 15, it is possible to omit the tapered portion 78. Specifically, the conductive partition member 70 has a first tubular portion 72A, a second tubular portion 72B, and a third tubular portion 72C. Each of the first tubular portion 72A, the second tubular portion 72B, and the third tubular portion 72C has a straight portion 86 extending in the passing direction of the wind (the arrow T direction) but does not have a tapered portion

In this case, for example, an electromagnetic wave EW that enters the annular air passage 68B of the conductive duct 62 repeatedly passes through the straight portion 86 of the second tubular portion 72B while drawing a wave form. At this time, the electromagnetic wave EW is gradually attenuated due to the above-described absorption loss A.

In the above embodiment, the widths W1, W2, and W3 of the plurality of annular air passages 68A, 68B, and 68C are increased from the center side of the fan module 42 toward the outer peripheral side thereof (W1 <W2 <W3). However, the widths of the plurality of annular air passages may be decreased from the center side of the fan module 42 toward the outer peripheral side thereof. The widths of the plurality of annular air passages may be equal to each other.

In the above embodiment, the chamfered portion 82 is provided at the inner peripheral surface 76B side of the end portion 76A of the first straight portion 76. However, the chamfered portion may be provided at the outer peripheral surface side of the end portion 76A of the first straight portion 76. The chamfered portion may be provided at each of the inner peripheral surface side and the outer peripheral surface side of the end portion 76A of the first straight portion 76. Furthermore, it is possible to omit the chamfered portion.

In the above embodiment, the plurality of tubular portions 72 form a finger guard. However, the plurality of tubular portions may not form a finger guard.

Each tubular portion 72 of the above embodiment has the first straight portion 76, the tapered portion 78, and the second straight portion 80. However, at least a straight portion or a tapered portion may be provided in each tubular portion.

The conductive partition member 70 of the above embodiment has a plurality of tubular portions 72. However, at least one tubular portion may be provided in the conductive partition member 70.

The conductive partition member is not limited to the tubular portions 72. For example, the conductive partition member may have a partition portion that partitions the air passage of the conductive duct along the passing direction of the wind and that partitions the air passage into a plurality of small air passages in the circumferential direction. For example, the conductive partition member may have a partition portion that partitions the air passage of the conductive duct along the passing direction of the wind and that partitions the air passage into a plurality of small air passages in a lattice manner.

The air passage of the conductive duct of the above embodiment has a circular shape. However, the shape of the air passage of the conductive duct is not limited to a circular shape, and may be, for example, an elliptical shape, a polygonal shape, or the like.

Similarly to this, in the above embodiment, the vent port of the conductive housing 12 has a circular shape. However, the shape of the vent port of the conductive housing is not limited to a circular shape, and may be, for example, an elliptical shape, a polygonal shape, or the like.

The duct module 60 of the above embodiment couples the air sending port 50B of the fan module 42 and the vent port 24 of the conductive housing 12. However, the duct module may couple, for example, the suction port of the fan module and the vent port of the conductive housing.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic device, comprising:
an electronic component;
a conductive housing that has electric conductivity and a vent port and houses the electronic component;
a fan that is housed within the conductive housing;
a conductive duct that has electric conductivity and couples the vent port and the fan; and
a conductive partition member that has electric conductivity, is provided in an air passage of the conductive duct, and partitions the air passage along a passing direction of wind.

2. The electronic device according to claim 1, wherein
the air passage has a circular shape, and
the conductive partition member is disposed in the air passage and includes a tubular portion that partitions the air passage into a plurality of small air passages.

3. The electronic device according to claim 2,
wherein the conductive partition member has a plurality of the tubular portions that have diameters different from each other.

4. The electronic device according to claim 2,
wherein the tubular portion includes an inclined portion inclined relative to the passing direction of the wind.

5. The electronic device according to claim 4,
wherein the inclined portion is configured to have a diameter that decreases from the fan side toward the vent port side of the conductive housing.

6. The electronic device according to claim 2, wherein
the small air passage located at a center of the air passage, among the plurality of small air passages, is a circular air passage that has a circular shape, and
the small air passage located at an outer peripheral side of the circular air passage, among the plurality of small air passages, is an annular air passage that has an annular shape.

7. The electronic device according to claim 6,
wherein the annular air passage located at an outermost periphery, among the plurality of annular air passages, has an air passage width larger than an air passage width of the annular air passage located at an innermost periphery.

8. The electronic device according to claim 7,
wherein the fan is a device that employs an axial flow method in which a wind speed of wind generated increases toward an outer peripheral side.

9. The electronic device according to claim 2,
wherein a chamfered portion is provided at an end portion of the tubular portion.

10. The electronic device according to claim 9,
wherein the chamfered portion is formed at the end portion of the tubular portion and at an inner peripheral surface side.

11. The electronic device according to claim 3,
wherein the plurality of tubular portions form a finger guard.

12. The electronic device according to claim 3,
wherein the plurality of tubular portions are coupled to each other via a coupling portion that extends in a radial direction of the air passage.

13. The electronic device according to claim 3,
wherein the plurality of tubular portions are coaxially disposed.

14. The electronic device according to claim 3,
wherein each tubular portion has a straight portion along the passing direction of the wind.

15. The electronic device according to claim 3, wherein
the conductive housing has a side wall portion, and
the vent port is provided in the side wall portion.
